(19) United States
(12) Patent Application Publication
(10) Pub. No.: US 2024/0083468 A1
(43) Pub. Date: Mar. 14, 2024

(54) MODELING PROCESS AND STRUCTURAL REPAIR OF A RAILWAY OR METAL CAR

(71) Applicant: MINETEC S.A., Santiago (CL)

(72) Inventors: Bernardo Luis VERA TORRES, Santiago (CL); Claudio Devon ZAMORANO JONES, Santiago (CL)

(73) Assignee: MINETEC S.A., Santiago (CL)

(21) Appl. No.: 18/463,915

(22) Filed: Sep. 8, 2023

(30) Foreign Application Priority Data
Sep. 9, 2022 (CL) 202202477

(51) Int. Cl. B61D 7/28; B61D 7/02; B61D 17/04; G06F 30/15

(52) U.S. Cl. CPC B61D 7/28; B61D 7/02; B61D 17/04; G06F 30/15

(57) ABSTRACT

Modeling process and structural repair of a railway or metal car to assemble a hopper with a self-supporting body different from the original hopper that is formed from steel plates on the structure of the car.

### TECHNICAL FIELD

The invention is developed in the field of maintenance and repair of cargo movement equipment, specifically, it refers to a process of modeling and structural repair of a railway or metalworker car to assemble a hopper with a self-supporting body, unlike the original hopper that is formed from steel plates on the structure of the car.

### DESCRIPTION OF THE PRIOR ART

Currently metal cars are hoppers completely covered with steel plates, which once worn present difficulties to make their change. Due to the above, it is common during the maintenance of said cars, that the steel plates of the metal cars are not replaced but rather that the worn surface is covered with new steel plates placed on top of the worn steel plates. This procedure decreases the reliability of the cars, increases their weight in each repair carried out and produces an overload of welding.

In the state of the art it is possible to find metal cars or railway wagons, being possible to cite the document CN203172636 that describes a mining wagon whose interior surface is covered by high molecular weight polyethylene membranes that reduce the possibility of mineral aggregates adhering to said surface of the mining wagon, allowing to increase its efficiency and its useful life. This document addresses the problem of wear due to corrosion and impacts due to the adherence of the mineral material transported by the wagons, however, no reference is made to repair procedures for the mining wagon when wear occurs or to the difficulty of replacement in the elements of the surface of a wagon.

To solve the problem, a hopper formed by a self-supporting body for metal rail cars is manufactured, which replaces the steel plates that form the hoppers commonly used in the state of the art, where the body of the hopper can be removed. easily when wear occurs, facilitating maintenance and whose shape also prevents the accumulation of remaining material or carryback in those worn or corroded areas of the trolleys.

### SUMMARY OF THE INVENTION

The invention refers to a repair and reconditioning process of a metal car with a hopper made of steel plates that allows the replacement of said hopper with a hopper made up of a complete body, which considers both operations prior to the execution of obtaining of data and parameters for the design of the new hopper as well as workshop operations for the application of design and improvement of structures that allow to achieve an adequate assembly of said new hopper.

This process makes it possible to obtain a metal cart that is easy to maintain, has a low accumulation of remaining material (carryback) and is low in weight.

mechanical type, can be included on the outer face of at least one wall of the hopper to agitate the material particles and generate the sliding it through the hopper, also reducing unloading times.

### BRIEF DESCRIPTION OF THE FIGURES

A detailed description of the invention will be carried out in conjunction with the figures that are part of this presentation, where it can be seen that:

FIG. 1 shows a front view of a metal cart according to the invention.

FIG. 2 shows a front view of the new full body hopper installed in the structure of the metal wagon.

FIG. 3 shows a perspective view of the structure of the metal wagon without the hopper installed.

FIG. 4 shows a perspective view of the new hopper installed in the structure of the metal cart and its edge joints.

FIG. 5 shows the new hopper installed in the structure of the metal car and the curved corners on its edges.

FIG. 6 shows a connection of the parts of the hopper by means of a corner connection with interior reinforcement.

FIG. 7 shows a union of the parts of the hopper by means of a “half round” union.

FIG. 8 shows a connection of the parts of the hopper by means of a corner plate.

FIG. 9 shows a diagram of the operation of a pivot bar and a mechanism for operating the gates of the metal cart.

FIG. 10 shows a bottom view of the drive mechanism of the gates of the metal car.

FIG. 11 shows the new hopper with a vibrator on the outside of a side wall.

FIG. 12 shows the new hopper with a vibrator on the outside of the front wall.

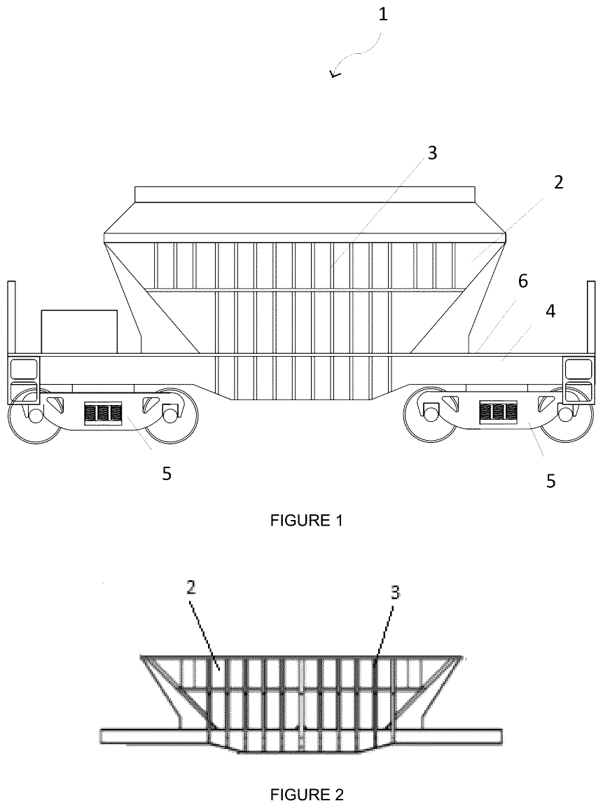

### DETAILED DESCRIPTION OF THE INVENTION

The invention refers to a repair and reconditioning process of a metal car (1) with a hopper made of steel plates, for the replacement of said hopper with a new hopper (2) formed by a self-supporting body that facilitates maintenance, decreases the accumulation of carryback material (carryback) and reduces weight.

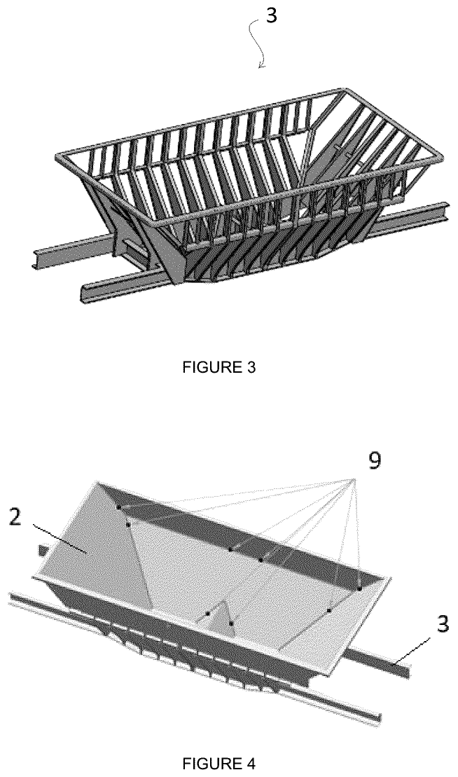

The metal cart (1) comprises a supporting structure (3) on which the steel hopper is mounted, made of steel plates, where said supporting structure (3) is mounted, in turn, on a base platform (4) mobile that allows its movement. In one modality, the mobile base platform (4) comprises, in its lower part, two bogies (5) located at each end to move the metal wagon (1). In addition, in its upper part, the base platform (4) includes, at one of its ends, a surface with a mesh-type floor (6) so that an operator can climb on it. FIG. 3 shows a preferred modality of the supporting structure (3) on which the hopper (2) is mounted, being formed by pokers and beams.

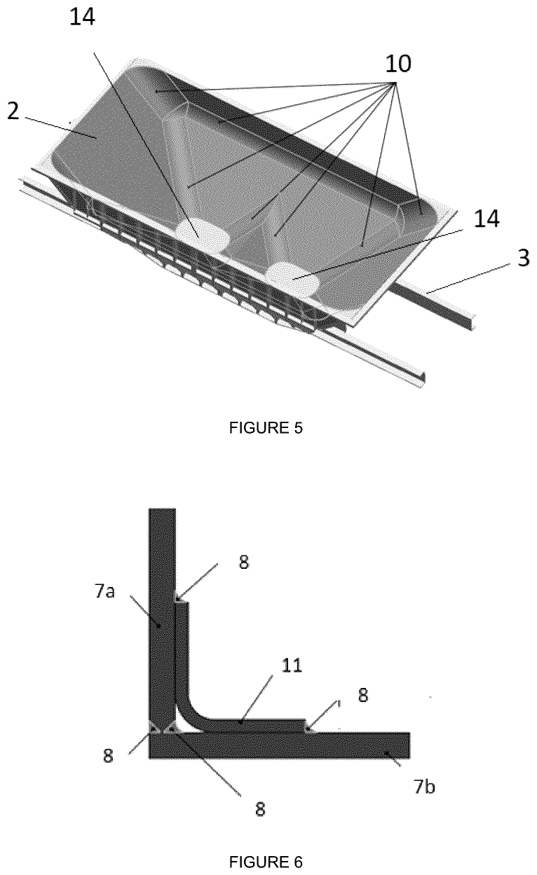

The objective of the invention is to replace the steel hopper of the metal cars (1) commonly used in the state of the art, with a new hopper (2) formed by a self-supporting body with a plurality of structural elements (7) that are They are manufactured separately and joined to form the structure of the new hopper (2) forming a self-supporting body that constitutes a single piece prior to its installation. In one embodiment, the structural elements are plates. The union of the structural elements (7) is carried out by means of welding (8) or another suitable means of union. FIG. 4 shows a modality where the union of the structural elements (7) form straight edges (9). FIG. 5 shows a modality where the union of the structural elements (7) correspond to corners or curved segments (10) that prevent the accumulation of material (carryback). In one embodiment, the structural elements (7) are made of HDPE or anti-abrasive steel.

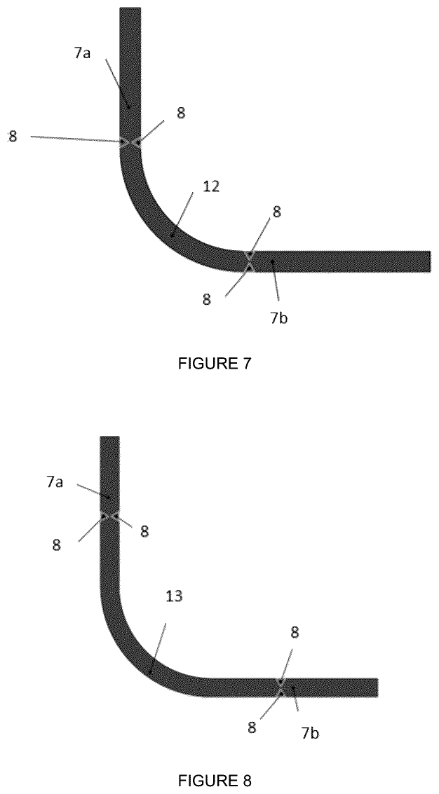

The joints of the structural elements (7) depend on their location in the structure of the new hopper (2), with the following types of joints present:
corner joint with internal reinforcement in which two structural elements (7a, 7b) are joined so that the end of a first structural element (7a) by welding (8), to the end of a face of a second structural element (7b), as shown in FIG. 6. In this joint, a curved inner reinforcement plate (11) can be used that covers the joint of the structural elements (7), the inner reinforcement plate (11) being joined at its ends, to each structural element (7a, 7b) by welding (8).
joint with a half round, where two structural elements (7) are joined using a corner half round (12) that corresponds to an intermediate curved element that includes two ends that are joined, respectively, to the end of a first structural element (7a) and to the end of a second structural element (7b), using welding (8), as shown in FIG. 7. In one embodiment, the half round corner (12) has a circular arc shape.
union by corner plate, where two structural elements (7) are joined using a corner plate (13) that corresponds to an intermediate curved element that includes two ends that are joined, respectively, to the end of a first structural element (7a) and to the end of a second structural element (7b) using welding (8), as shown in FIG. 8. In one embodiment, the corner plate (13) has an L-shape whose apex is curved or rounded.

The half-round joints and the corner plate joint allow obtaining curved segments that define corners or curved segments (10) in the new hopper (2).

In one embodiment, the inner reinforcing plate (11), the corner half round (12) and/or the corner plate (13) are made of HDPE or anti-abrasive steel.

In one embodiment, the weld (8) at the joints of the structural elements (7) is an HDPE extrusion weld.

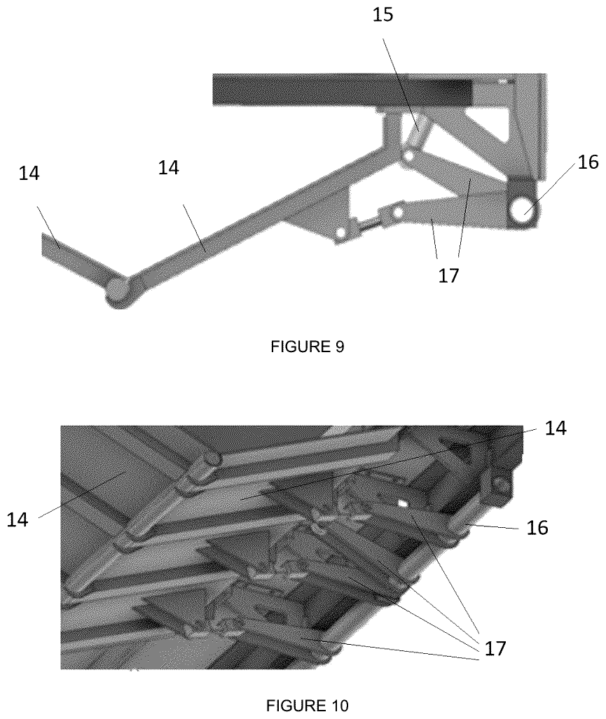

The new hopper (2) also includes, at its bottom, two gates (14) that make it possible to regulate the discharge of material. The gates (14) are made up of steel plates that are each actuated by a drive mechanism. In FIG. 9, a modality of the actuation mechanism is shown, which comprises an axis (16) connected to an actuation unit, which comprises a pneumatic cylinder (15) that commands the axis (16) and at least two arms (17).) that are connected to said shaft (16) and to the gates (14), as shown in FIG. 10, which allow the transmission of movement for the opening or closing of the gates when actuating said pneumatic cylinder (15). The actuation mechanism also allows the actuation of certain locks on the gates (14) that lock them and prevent their opening, allowing their hermetic closure. In one embodiment, each drive mechanism includes four arms (17) to ensure proper opening and closing of each gate (14). Said actuating mechanism has the advantage of being easy to maintain and operate, reducing the tare weight of the metal cart (1) by approximately 900 kilos and allows the operators to only intervene in the operating valves to actuate the mechanism.

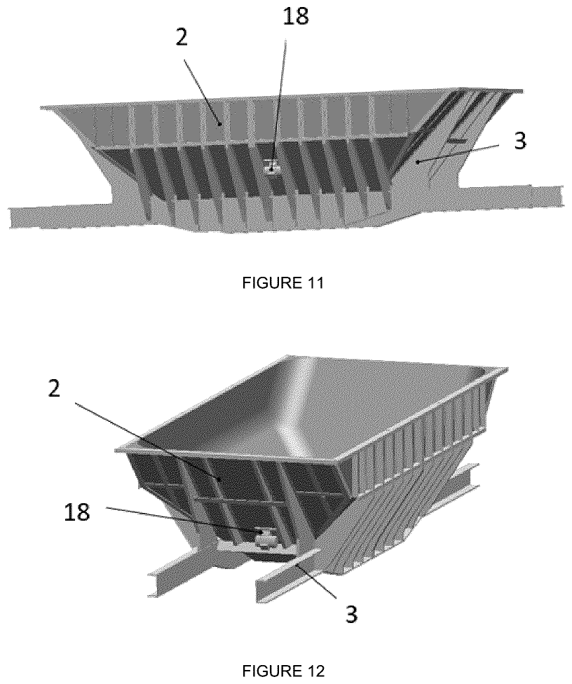

The new hopper (2) can also comprise at least one mechanical vibrator (18) to facilitate the unloading of the material in the new hopper (2) and avoid the accumulation of remaining material. The mechanical vibrator (18) generates the agitation of the material particles inside the new hopper (2) producing a fluidization effect of the solid material, allowing it to slide more easily through the hopper (2), reducing well, download time. In one modality, the mechanical vibrator (18) is installed in the lower portion of the new hopper (2) to facilitate the passage of the material through the gates (14), specifically, the mechanical vibrator is arranged on the outer face of at least one outer wall of the new hopper (2), preferably on the outer face of a side wall or on the outer face of the front wall, as shown in FIGS. 11 and 12, respectively.

The process to recondition the metal cart (1) for the replacement of the steel hopper with the new hopper (2), includes a first stage of scanning and modeling of the new hopper (2) for the metal cart (1), which comprises the following steps:
Scanning of the existing car: it consists of submitting the metal car (1) to a 3D scanning system, preferably with a laser scanner, to gather data on its shape in such a way to have a 3D plan that allows obtaining the dimensions and arrangement of structural elements of the metal cart (1), particularly the hopper.
Modeling and calculation of the hopper: with the data obtained from the scan of the metal cart (1), a precise model is generated for the geometry of the new hopper (2) that will be mounted on the metal cart (1) based on the shape of the hopper original steel.
Modeling and calculation of the reinforcement of the supporting structure (3): with the data already defined, a reinforcement is modeled and calculated for the supporting structure (3) of the metal wagon (1) adding and/or modifying new elements until obtaining the final model for adapt it to the new hopper (2), if applicable.
modeling and plans: from the final model, the final plans of the new hopper (2) are generated for the repair of the metal wagon (1).
After the first stage, a second stage of execution and structural repair of the metal wagon (1) and installation of the new hopper (2) on the metal wagon (1) is carried out. This stage includes the following actions:
Disassembly of damaged structures and plates: consists of removing the original steel hopper, removing the steel plates and removing the damaged areas of the supporting structure (3) removing the damaged material; clean the supporting structure (3) to remove undesired elements due to contamination by the hauling material; and removal of remaining material due to previous repairs. In addition, the repair of stiffeners and beams is carried out in poor condition of the supporting structure (3) and the replacement of the mesh type floor (6) of the metal car (1) by a grill type floor (grating) is also considered to improve its resistance and durability, giving greater safety conditions to the operators.
Cleaning: consists of cleaning the surface of the metal cart (1), preferably by sandblasting in order to improve the adhesion of the surface for a painting process of the metal cart (1), thus leaving the components in optimal conditions for reinforcement and repair of the supporting structure (3).
Repair and adaptation of the structural reinforcements of the supporting structure (3): consists of replacing the damaged parts and reinforcing the supporting structure (3) with structural reinforcements to facilitate the assembly of the new hopper (2) to join its body at specific points of the supporting structure (3), so that the new hopper (2) can be easily placed and removed, being an interchangeable element. In one modality, structural reinforcements are placed in the corners of the upper part of the supporting structure (3) that allow the new hopper (2) to be supported.
Manufacture of the new hopper (2): it consists of manufacturing the structural elements (7) that form the self-supporting body of the new hopper (2), where the form of manufacture is carried out after evaluating different options of elements to obtain a better configuration that allows to reduce the number of joints/edges. The new hopper (2) is manufactured in such a way that it comprises a self-supporting body that constitutes a single piece with corners or curved segments (10) at its junctions or edges to prevent the accumulation of material and two openings in its bottom. The joints of the structural elements (7) are obtained by welding (8)
Modify the gate system: it consists of installing the gates (14) in the openings at the bottom of the new hopper (2) and placing each drive mechanism in the gates (14), arranging a shaft (16) in each gate (14), and connecting the drive unit between the shaft (16) and the gate, connecting the pneumatic cylinder (15) and the at least two arms (17) to the shaft (16) at one end and at the other end to the gate (14). In one embodiment, the gates (14) are protected using coatings. In addition, locks are installed on the gates (14) that allow the hermetic closure of these through the drive mechanism.
Assembling the new hopper (2) on the metal cart (1): consists of assembling the new hopper (2) on the supporting structure (3), being placed and attached to the structural reinforcements of the supporting structure (3).
Car painting (1): consists of applying paint to the metal car (1) to finish the repair and reconditioning process.
In accordance with the above, the process of structural repair and coating of a metal car (1), includes the stages of:
i. Provide the metal car (1) to be repaired, which includes:
a mobile base platform (4) that has a supporting structure (3) mounted, which, in turn, has a hopper made of steel plates mounted, wherein said supporting structure (3) is formed by pokers and beams;
ii. Scan the metal car (1) to obtain a 3D plan of the dimensions and arrangement of elements;
iii. Model and calculate the geometry of the new hopper (2) from the scan of the metal car (1);
iv. Remove the steel hopper from the metal cart (1);
v. Repair and adapt the supporting structure (3) for the assembly of the new hopper (2);
vi. Manufacture a plurality of structural elements (7) that form the new hopper (2);
vii. Join the structural elements (7) so that the new hopper (2) includes corners or curved segments (10), avoiding the accumulation of material and two openings in its bottom;
viii. Install gates (14) in the bottom openings of the new hopper (2);
ix. Mounting a drive mechanism on each gate (14) to open and close said gates (14);
x. Assemble the new hopper (2) on the supporting structure (3) of the metal cart (1).

In one modality, the scanning of the metal car (1) is carried out by means of a laser scanner or another suitable method.

In one modality, optionally, after modeling and calculating the geometry of the new hopper (2), a reinforcement is calculated for the supporting structure (3) of the metal truck (1) adding and/or modifying elements to adapt it to the new hopper (2).

The removal of the steel hopper from the metal cart (1) is done by removing the steel plates that make up said hopper.

The repair of the supporting structure (3) consists of removing the damaged material; clean hauling material from the supporting structure (3) and removal of remaining material due to previous repairs. In one modality, if required, the repair and/or replacement of the damaged parts or parts in poor condition of the supporting structure (3) is carried out, such as stiffeners and beams.

In one modality, the adaptation of the supporting structure (3) consists of adding structural reinforcements to facilitate the assembly of the new hopper (2) to join its body at specific points of the supporting structure (3), facilitating its assembly.

Thus, the number and shape of the manufactured structural elements (7) consider a configuration that allows the number of joints/edges of the new hopper (2) to be reduced.

Also, the joints of the structural elements (7) are made by means of corner joints with internal reinforcement, half-round joints and/or joints by means of a corner plate, where said joints are preferably made with welding (8). The corner joint with interior reinforcement is made by joining the ends of two structural elements (7), where a curved interior reinforcement plate (11) is added that covers the union of said structural elements (7), generating a curved segment, the inner reinforcement plate (11) being attached at its ends to each structural element. The half-round connection is made by connecting two HDPE elements (7) using a corner half-round (12) that corresponds to an intermediate curved element that includes two ends that are joined, respectively, to the end of one end of one element. structural, wherein, preferably, the half round corner (12) has a circumferential arc shape. The joint by means of a corner plate is made by connecting two structural elements (7) using a corner plate (13) that corresponds to an intermediate curved element, where each end is joined, respectively, to one end of a structural element (7), wherein, preferably, the corner plate (13) has an L shape whose vertex is curved or rounded. In this way, the new hopper (2) includes curved corners or segments (10) to avoid the accumulation of material.

In one embodiment, mounting the drive mechanisms consists of arranging a shaft (16) in the gate (14) and connecting a drive unit between the shaft (16) and the gate (14) by connecting a pneumatic cylinder to the shaft (16) and at least two arms (17) at one end to the shaft (16) and at the other end to the gate (14) so as to allow said gate (14) to be opened and closed. In addition, locks are installed on the gates (14) that allow the hermetic closure of these by means of the drive mechanism.

Optionally, the gates (14) are protected using a coating.

Additionally, once the new hopper (2) is mounted on the supporting structure (3), in order to facilitate the unloading of the material in the new hopper (2) and avoid the accumulation of remaining material, at least one mechanical vibrator is installed. (18) on the outside of a wall of the new hopper (2) to facilitate the passage of the material through the gates (14). In one embodiment, at least one mechanical vibrator (18) is installed on the outer face of at least one side wall of the new hopper (2) or on the outer face of the front wall of the new hopper (2).

Once the first stage of scanning and modeling has been carried out, which allows obtaining the new hopper (2) for the reconditioning of the metal wagon (1), it is possible to carry out the stage of execution and structural repair for other equivalent metal wagons (1) without carrying out said first stage. In an equivalent way, it is possible to manufacture new metal cars equivalent to the metal car (1) from which the new hopper (2) was generated, so that said new metal cars include the new hopper (2) from its manufacture.

1. A process of structural repair and coating of a metal car, which facilitates maintenance operations, reduces the accumulation of remaining material (carryback) and decreases the weight of said metal car, wherein it includes the stages of:
i. Provide the metal car to be repaired, which includes:
a mobile base platform that has a supporting structure mounted, which, in turn, has a hopper made of steel plates mounted, wherein said supporting structure is formed by pokers and beams;
ii. scan the metal car to obtain a 3D plan of the dimensions and arrangement of elements;
iii. model and calculate the geometry of a new hopper from the scan of the metal car;
iv. remove the steel hopper from the metal car;
v. repair and adapt the supporting structure for the assembly of the new hopper;
vi. manufacture a plurality of structural elements that form the new hopper;
vii. join the structural elements so that the new hopper comprises a self-supporting body in one piece that includes corners or curved segments to prevent material accumulation and two openings in its bottom;
viii. install gates in the bottom openings of the new hopper;
ix. mounting a drive mechanism on each gate to open and close said gates;
x. Mount the new hopper on the supporting structure of the metal car.

2. The process according to claim 1, wherein at least one of the following is true:
the scanning of the metal car is carried out by means of a laser scanner or another suitable method;
after stage iii a reinforcement for the supporting structure of the metal car is calculated by adding and/or modifying elements to adapt it to the new hopper; or
the removal of the steel hopper from the metal car is carried out by removing the steel plates that make up said hopper.

3. The process according to claim 1, wherein the repair of the supporting structure consists of removing the damaged material; clean hauling material from the supporting structure and removal of remaining material due to previous repairs.

4. The process according to claim 3, wherein the repair of the supporting structure further comprises repairing and/or replacing damaged or poorly maintained parts of the supporting structure, such as stiffeners and beams.

5. The process according to claim 3, wherein the adaptation of the supporting structure consists of adding structural reinforcements that facilitate the assembly of the new hopper.

6. The process according to claim 5, wherein the structural reinforcements are added in the corners of the upper part of the supporting structure.

7. The process according to claim 1, wherein the number and shape of the structural elements manufactured consider a configuration that allows the number of joints/edges of the new hopper to be reduced.

8. The process according to claim 1, wherein the joints of the structural elements are carried out by means of corner joints with internal reinforcement, half round joint and/or joint by means of a corner plate.

9. The process according to claim 8, wherein at least one of the following is true:
the corner joint with internal reinforcement is made by joining the ends of two structural elements, where a curved internal reinforcement plate is added that covers the joint of said structural elements, generating a curved segment, the inner reinforcement plate being attached at its ends to each structural element; or
the union by means of a corner plate is carried out by connecting two structural elements using a corner plate that corresponds to a curved intermediate element where each end is joined, respectively at one end of a structural element.

10. The process according to claim 8, wherein the half-round connection is made by connecting two structural elements using a corner half-round that corresponds to a curved intermediate element that includes two ends that are joined, respectively, at the end of a structural element.

11. The process according to claim 10, wherein the union by means of a corner plate is carried out by connecting two structural elements using a corner plate that corresponds to a curved intermediate element where each end is joined, respectively at one end of a structural element; and
the half round corner has a circumferential arc shape.

12. The process according to claim 1, wherein the corner plate has an L shape whose vertex is curved or rounded.

13. The process according to claim 1, wherein at least one of the following is true:
the assembly of the drive mechanisms consists of arranging an axis in the gate; connect a drive unit between the shaft and the gate by connecting a pneumatic cylinder to the shaft and at least two arms at one end to the shaft and at the other end to the gate in a way that allows opening and closing said gate; and install locks on the gates that allow the hermetic closing of these gates by means of the drive mechanism; or
the gates are protected using a coating.

14. The process according to claim 1, wherein once the new hopper is mounted on the supporting structure at least one mechanical vibrator is installed to agitate the material in the hopper to facilitate its removal. download.

15. The process according to claim 14, wherein at least one of the following is true:
the at least one mechanical vibrator is installed on the outer face of at least one side wall of the new hopper; or
at least one mechanical vibrator is installed on the outer face of the front wall of the new hopper.

16. A metal car, which facilitates maintenance operations, reduces the accumulation of remaining material (carryback) and decreases the weight of said metal car, wherein it comprises:
a mobile base platform;
a supporting structure mounted on the mobile base platform, being formed by pokers and beams;
a hopper, mounted on the supporting structure, formed by a self-supporting body, formed by a plurality of structural elements, which constitutes a single piece, includes corners or curved segments to avoid accumulation of material and two openings in its bottom;
a gate in each opening at the bottom of the hopper to regulate the discharge of material, which are actuated by a drive mechanism.

17. A metal car according to claim 16, wherein at least one of the following is true:
the structural elements are joined by means of corner joints with internal reinforcement, half round joint and/or joint by means of a corner plate;
the drive mechanism comprises an axis connected to a drive unit, which comprises a pneumatic cylinder that commands the axis and at least two arms that are connected to said axis and to the gates that allow to transmit the movement for the opening or closing of the gates when actuating said pneumatic cylinder;
the gates include locks, actuated by the drive mechanism, which lock them and prevent their opening; or
the gates are made of steel plates.

18. A metal car according to claim 16, wherein the metal car comprises at least one mechanical vibrator to shake the material in the hopper to facilitate its unloading.

19. A metal car according to claim 18, wherein at least one of the following is true:
The metal car is installed on the outside of at least one side wall of the new hopper; or
at least one mechanical vibrator is installed on the outer face of the front wall of the new hopper.

20. A metal car according to claim 16, wherein the structural elements are made of HDPE or anti-abrasive steel.
